(19) United States
(12) Patent Application Publication
(10) Pub. No.: US 2021/0036202 A1
(43) Pub. Date: Feb. 4, 2021

(54) THERMOELECTRIC CONVERSION MODULE AND METHOD FOR MANUFACTURING SAME

(71) Applicant: LINTEC Corporation, Itabashi-ku (JP)

(72) Inventors: Yusuke HARA, Shinagawa-ku (JP); Wataru MORITA, Saitama-shi (JP); Kunihisa KATO, Warabi-shi (JP); Tsuyoshi MUTO, Saitama-shi (JP)

(73) Assignee: LINTEC Corporation, Itabashi-ku (JP)

(21) Appl. No.: 16/498,272

(22) PCT Filed: Oct. 24, 2017
(86) PCT No.: PCT/JP2017/038344

§ 371 Date: Sep. 26, 2019

(30) Foreign Application Priority Data
Mar. 30, 2017 (JP) 2017-068806

(51) Int. Cl. H01L 35/32; H01L 35/02; H01L 35/34

(52) U.S. Cl. CPC H01L 35/32; H01L 35/34; H01L 35/02

(57) ABSTRACT

The present invention is to provide a thermoelectric conversion module capable of maintaining a thermoelectric performance and revealing excellent insulation properties and a method of producing the same. Provided are a thermoelectric conversion module including a heat dissipation layer via an insulating layer on at least one face of a thermoelectric element layer being one in which a p-type thermoelectric element layer and an n-type thermoelectric element layer are alternately arranged to be adjacent to each other in the in-plane direction and disposed in series, wherein the insulating layer has an elastic modulus at 23° C. of 0.1 to 500 GPa, and a method of producing the same.

### TECHNICAL FIELD

The present invention relates to a thermoelectric conversion module and a method of producing the same.

### BACKGROUND ART

As an energy conversion technology utilizing thermoelectric conversion, a thermoelectric power generation technology and a Peltier cooling technology have been known. The thermoelectric power generation technology is a technology that utilizes conversion from thermal energy to electric energy through the Seebeck effect, and the technology is attracting increasing attention particularly as an energy saving technology capable of recovering, as electric energy, unused waste heat energy formed from the fossil fuel resources or the like used in buildings, factories, and the like. The Peltier cooling technology is a technology that utilizes conversion from electric energy to thermal energy through the Peltier effect in contrast to the thermoelectric power generation, and the technology is being used in a wine refrigerator, a small portable refrigerator, cooling for a CPU used in a computer or the like, and a component or device that requires precise temperature control, such as temperature control of a semiconductor laser oscillator for optical communication.

In a thermoelectric conversion module utilizing such thermoelectric conversion, a high thermal conductive layer having electrical conductivity is occasionally provided as a heat dissipation layer relative to a thermoelectric element layer, and in the case where insulation properties with the thermoelectric element layer were insufficient, namely at the time of production or at the time of use inclusive of handling, there is involved such a problem that a short circuit is generated between the high thermal conductive layer and the thermoelectric element layer, whereby a thermoelectric performance is lowered, or the resultant does not function as the thermoelectric conversion module. In addition, in the case where an instillation face (e.g., an external heat exhaust face or a heat discharging face) of the thermoelectric conversion module has, for example, an electrical conductive site and is a curved face and/or face of irregularities, a short circuit is generated between the instillation face and the thermoelectric element layer at the time of instillation or at the time of long-term use, and as a result, there is a case where even if the heat dissipation layer of the thermoelectric conversion module does not have electrical conductivity, the same problem as that mentioned above is caused.

PTL 1 discloses a flexible thermoelectric conversion element in which a high thermal conductive layer is laminated on an in-plane type thermoelectric conversion element via a pressure sensitive adhesive layer.

### CITATION LIST

### Patent Literature

PTL 1: Japanese Patent Application No. 2017-013006

### SUMMARY OF INVENTION

### Technical Problem

However, as for PTL 1, there is a possibility that an elastic modulus of the pressure sensitive adhesive layer is not sufficient, and there is a concern that at the time of production or at the time of use inclusive of handling, the high thermal conductive layer composed of a metal breaks through the pressure sensitive adhesive layer, a short circuit is generated between the high thermal conductive layer and the thermoelectric element layer, whereby a thermoelectric performance is lowered, or the resultant does not function as the flexible thermoelectric conversion element. In addition, even in the case where the aforementioned flexible thermoelectric conversion element is installed on the aforementioned instillation face, etc. having an electrical conductive site, there is a concern that the same problem is caused.

In view of the aforementioned problems, a problem of the present invention is to provide a thermoelectric conversion module capable of maintaining a thermoelectric performance and revealing excellent insulation properties and a method of producing the same.

### Solution to Problem

In order to solve the aforementioned problem, the present inventors made extensive and intensive investigations. As a result, it has been found that the aforementioned problem is solved by allowing an insulating layer having an elastic modulus of a specified range to intervene between a thermoelectric element layer and a heat dissipation layer, thereby leading to accomplishment of the present invention.

Specifically, the present invention provides the following (1) to (10).
(1) A thermoelectric conversion module including a heat dissipation layer on at least one face of a thermoelectric element layer via an insulating layer, the thermoelectric element layer being one in which a P-type thermoelectric element layer and an N-type thermoelectric element layer are alternately arranged to be adjacent to each other in the in-plane direction and disposed in series, wherein the insulating layer has an elastic modulus at 23° C. of 0.1 to 500 GPa.
(2) The thermoelectric conversion module as set forth in the above (1), wherein the insulating layer is composed of a resin or an inorganic material.
(3) The thermoelectric conversion module as set forth in the above (1) or (2), wherein the insulating layer has a thickness of 1 to 150 μm.
(4) The thermoelectric conversion module as set forth in any of the above (1) to (3), which includes the heat dissipation layer on one face of the thermoelectric element layer via the insulating layer, and further includes a substrate on the other face of the thermoelectric element layer.
(5) The thermoelectric conversion module as set forth in the above (4), further including a heat dissipation layer on the face of the substrate on the side opposite to the thermoelectric element layer.
(6) The thermoelectric conversion module as set forth in any of the above (1) to (5), wherein the heat dissipation layer is composed of at least one selected from the group consisting of a metal material, a ceramic material, a mixture of a metal material and a resin, and a mixture of a ceramic material and a resin.
(7) The thermoelectric conversion module as set forth in any of the above (1) to (6), wherein the dissipation layer has a thermal conductivity of 5 to 500 W/(m·K).
(8) The thermoelectric conversion module as set forth in the above (4) or (5), wherein the substrate is a film substrate.
(9) The thermoelectric conversion module as set forth in any of the above (1) to (8), further including a covering layer.
(10) A method of producing a thermoelectric conversion module which is the thermoelectric convention module as set forth in any of the above (1) to (9), the method including a step of forming the thermoelectric element layer; a step of forming the insulating layer; and a step of forming the heat dissipation layer, wherein the insulating layer having an elastic modulus at 23° C. of 0.1 to 500 GPa.

### Advantageous Effects of Invention

In accordance with the present invention, it is possible to provide a thermoelectric conversion module capable of maintaining a thermoelectric performance and revealing excellent insulation properties and a method of producing the same.

### BRIEF DESCRIPTION OF DRAWINGS

FIG. 1 is a cross-sectional view showing an embodiment of a thermoelectric conversion module of the present invention.

FIG. 2 is a cross-sectional view showing a thermoelectric conversion module used in the Examples of the present invention.

FIG. 3 is a cross-sectional view showing other embodiment of a thermoelectric conversion module of the present invention.

FIG. 4 is a plan view showing an example of a disposition of electrodes and thermoelectric elements on the substrate configuring a part of a thermoelectric conversion module used in the Examples of the present invention.

### DESCRIPTION OF EMBODIMENTS

### [Thermoelectric Conversion Module]

The thermoelectric conversion module of the present invention is a thermoelectric conversion module including a heat dissipation layer on at least one face of a thermoelectric element layer via an insulating layer, the thermoelectric element layer being one in which a P-type thermoelectric element layer and an N-type thermoelectric element layer are alternately arranged to be adjacent to each other in the in-plane direction and disposed in series, wherein the insulating layer has an elastic modulus at 23° C. of 0.1 to 500 GPa.

By disposing the insulating layer having a specified elastic modulus on at least one face of the thermoelectric element layer, a short circuit between the thermoelectric element layer and the electric conductive site of the heat dissipation layer and/or a short circuit between the thermoelectric element layer and the electric conductive site, etc. of the instillation face of the thermoelectric conversion module can be suppressed without the lowering of a thermoelectric performance.

The thermoelectric conversion module of the present invention is described by reference to the accompanying drawings.

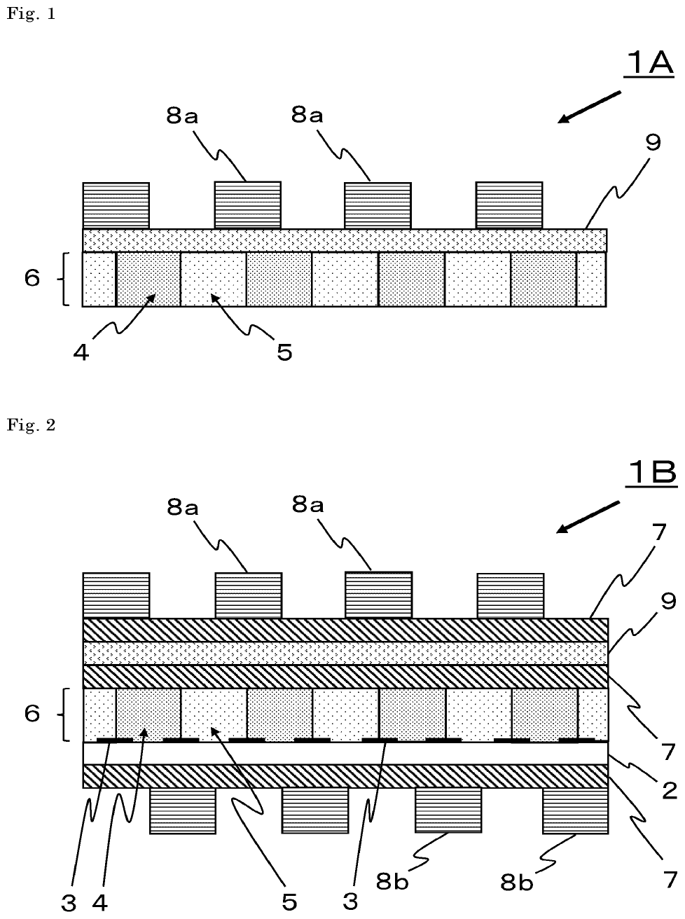

FIG. 1 is a cross-sectional view showing an embodiment of the thermoelectric conversion module of the present invention. A thermoelectric conversion module 1A includes an insulating layer 9 and a heat dissipation layer 8a in this order on one face of a thermoelectric element layer 6 in which a P-type thermoelectric element layer 5 and an N-type thermoelectric element layer 4 are alternately arranged to be adjacent to each other in the in-plane direction and disposed in series.

FIG. 2 is a cross-sectional view showing the thermoelectric conversion module used in the Examples of the present invention. A thermoelectric conversion module 1B includes a thermoelectric element layer 6, a covering layer 7, an insulating layer 9, a covering layer 7, and a heat dissipation layer 8a in this order on the face of a substrate 2 provided with an electrode 3 and further includes a covering layer 7 and a heat dissipation layer 8b on the face of the substrate 2 on the opposite side to the thermoelectric element layer 6.

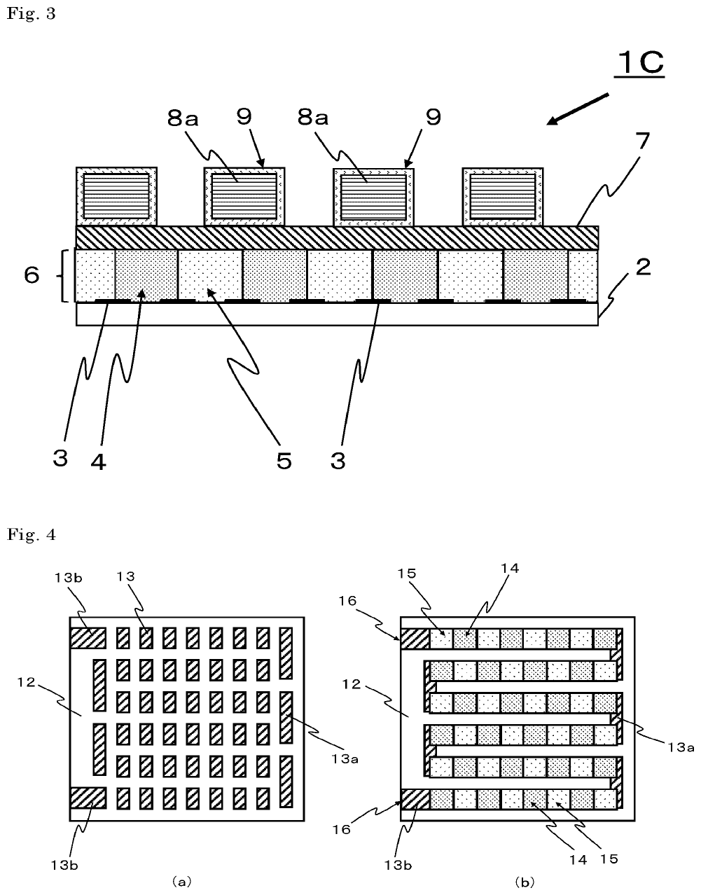

FIG. 3 is a cross-sectional view showing other embodiment of the thermoelectric conversion module of the present invention. A thermoelectric conversion module 1C includes a thermoelectric element layer 6 and a covering layer 7 in this order on the face of a substrate 2 provided with an electrode 3 and further includes a heat dissipation layer 8a covered by an insulating layer 9.

As shown in FIG. 1, the thermoelectric conversion module of the present invention includes the heat dissipation layer on at least one face of the thermoelectric element layer via the insulating layer, the thermoelectric element layer being one in which the P-type thermoelectric element layer and the N-type thermoelectric element layer are alternately arranged to be adjacent to each other in the in-plane direction and disposed in series.

Preferably, the heat dissipation layer is included on one face of the thermoelectric element layer via the insulating layer, and a substrate is provided on the other face thereof. In addition, from the viewpoint of a thermoelectric performance, it is more preferred that a heat dissipation layer is further included on the face of the substrate on the side opposite to the thermoelectric element layer.

### <Insulating Layer>

The thermoelectric conversion module of the present invention includes the insulating layer. The insulating layer which is used in the present invention is able to suppress a short circuit between the thermoelectric element layer and the electric conductive site of the heat dissipation layer and/or a short circuit between the thermoelectric element layer and the electric conductive site, etc. on the instillation face of the thermoelectric conversion module.

Though the insulating layer which is used in the present invention is disposed between the thermoelectric element layer and the heat dissipation layer, the insulating layer is not particularly limited so long as it is disposed therebetween; and the insulating layer may be brought into direct contact with the thermoelectric element layer or may be provided via a covering layer as mentioned later so long as the thermoelectric performance can be maintained. In addition, the insulating layer may be brought into direct contact with the heat dissipation layer or may be provided via a covering layer. As shown in FIG. 3, the insulating layer may cover the heat dissipation layer. Furthermore, the insulating layer may be disposed so as to be sandwiched by the covering layer, or two or more thereof may be disposed.

The insulating layer may have adhesiveness. When the insulating layer has adhesiveness, it becomes easy to laminate the insulating layer on other layer or to laminate other layer on the insulating layer.

The elastic modulus at 23° C. of the insulating layer is 0.1 to 500 GPa. When the elastic modulus is less than 0.1 GPa, the strength of the insulating layer is lowered, so that the heat dissipation layer is liable to pierce the insulating layer; and in the case where the heat dissipation layer has the electrical conductive site, a short circuit with the thermoelectric element layer is liable to be generated. In addition, when the elastic modulus is more than 500 GPa, when bent, generation of a crack or like, or lowering of flexibility results. The elastic modulus at 23° C. of the insulating layer is preferably 0.1 to 400 GPa, more preferably 0.1 to 100 GPa, and still more preferably 0.1 to 10 GPa. When the elastic modulus falls within the aforementioned range, the short circuit between the electrical conductive site of the heat dissipation layer and the thermoelectric element layer is suppressed, and the thermoelectric performance is maintained. In addition, the case where the installation face of the thermoelectric conversion module has the electrical conductive site is also the same as above.

The insulating layer is not particularly limited so long as it has insulation properties, and its elastic modulus falls within the prescribed range of the present invention. However, the insulating layer is preferably composed of a resin or an inorganic material, and from the viewpoint of flexibility, it is more preferably composed of a resin.

Though the resin is not particularly limited, examples thereof include a resin film.

Examples of the resin which is used for the resin film include a polyimide, a polyamide, a polyamide-imide, a polyphenylene ether, a polyetherketone, a polyetheretherketone, a polyolefin, a polyester, a polycarbonate, a polysulfone, a polyether sulfone, a polyphenylene sulfide, a polyarylate, a nylon, an acrylic resin, a cycloolefin-based polymer, and an aromatic polymer.

Of these, examples of the polyester include polyethylene terephthalate (PET), polybutylene terephthalate, polyethylene naphthalate (PEN), and a polyarylate. Examples of the cycloolefin-based polymer include a norbornene-based polymer, a monocyclic cycloolefin-based polymer, a cyclic conjugated diene-based polymer, a vinyl alicyclic hydrocarbon, and a hydrogenated product thereof.

Of the resins which are used for the resin film, polyethylene terephthalate (PET), polyethylene naphthalate (PEN), and a nylon are preferred from the viewpoint of cost and heat resistance.

From the viewpoint of control of elastic modulus and control of thermal conductivity, a filler may be contained in the resin.

Examples of the filler which is added to the resin film include magnesium oxide, anhydrous magnesium carbonate, magnesium hydroxide, aluminum oxide, boron nitride, aluminum nitride, and silicon oxide. Of these, aluminum oxide, boron nitride, aluminum nitride, and silicon oxide are preferred from the viewpoint of control of elastic modulus, thermal conductivity, and so on.

The inorganic material is not particularly limited, and examples thereof include silicon oxide, aluminum oxide, magnesium oxide, calcium oxide, zirconium oxide, titanium oxide, boron oxide, hafnium oxide, barium oxide, boron nitride, aluminum nitride, and silicon carbide. Of these, silicon oxide and aluminum oxide are preferred from the viewpoint of cost, stability, and easiness of availability.

The thickness of the insulating layer is preferably 1 to 150 μm, more preferably 2 to 140 μm, still more preferably 3 to 120 μm, and especially preferably 5 to 100 μm. When not only the elastic modulus of the insulating layer falls within the range of the present invention, but also the thickness of the insulating layer falls within this range, the electrical conductive site of the heat dissipation layer hardly pierces the insulating layer, the short circuit with the thermoelectric element layer is suppressed, and the thermoelectric performance is maintained. In addition, the case where the instillation face of the thermoelectric conversion module has the electrical conductive site is also the same as above.

From the standpoint of securing the insulation properties, the volume resistivity of the insulating layer is preferably 1×10⁸ Ω·cm or more, more preferably 1×10⁹ Ω·cm or more, and still more preferably 1.0×10¹⁰ Ω·cm or more.

The volume resistivity is a value measured with a resistivity meter (MCP-HT450, manufactured by Mitsubishi Chemical Analytech Co., Ltd.) after allowing the insulating layer to stand in an environment at 23° C. and 50% RH for one day.

### <Heat Dissipation Layer>

The thermoelectric conversion module of the present invention includes the heat dissipation layer on at least one face of the thermoelectric element layer via the insulating layer. In addition, the heat dissipation layer may be brought into direct contact with the insulating layer or may be provided via the covering layer.

In particular, the heat dissipation layer which is used in the present invention is able to efficiently give a temperature difference between the thermoelectric element layers disposed in the in-plane direction.

Though the disposition of the heat dissipation layer which is used in the present invention is not particularly limited, it is necessary to properly regulate the disposition of the thermoelectric element layers of the thermoelectric conversion module to be used, namely the P-type thermoelectric element layer and the N-type thermoelectric element layer, and shapes thereof. In the present invention, in view of the fact that the disposition of the P-type thermoelectric element layer and the N-type thermoelectric element layer is, for example, an in-plane type as shown in FIG. 2, the disposition is made as in the heat dissipation layers 8a and 8b in the in-plane direction of the surface of the covering layer 7. In this case, the temperature difference can be given in the in-plane direction of the thermoelectric element layer. A ratio at which the aforementioned heat dissipation layers are positioned is preferably 0.30 to 0.70, more preferably 0.40 to 0.60, still more preferably 0.48 to 0.52, and especially preferably 0.50 relative to the overall width in the series direction being occupied by a pair of the P-type thermoelectric element layer and the N-type thermoelectric element layer. When the aforementioned ratio falls within this range, the heat can be selectively dissipated in a specified direction, and the temperature difference can be efficiently given in the in-plane direction. Furthermore, it is preferred that the heat dissipation layers are disposed such that they are not only satisfied with the foregoing requirements but also made symmetrical to a connection part corresponding to a pair of the P-type thermoelectric element layer and the N-type thermoelectric element layer in the series direction.

From the viewpoint of thermoelectric performance, the heat dissipation layer which is used in the present invention is formed of a high thermal conductive material. Though a method of forming the heat dissipation layer is not particularly limited, examples thereof include a method in which a high thermal conductive material in a sheet-like form is subjected in advance to a known physical treatment or chemical treatment, mainly those in the photolithography, or a combination thereof, thereby processing it into a predetermined pattern shape.

Examples of a material of the heat dissipation layer include a metal material, a ceramic material, a carbon-based material, such as a carbon fiber, and a mixture of such a material with a resin. Of these, the heat dissipation layer is composed of preferably at least one selected from the group consisting of a metal material, a ceramic material, a mixture of a metal material and a resin, and a mixture of a ceramic material and a resin, and more preferably at least one selected from the group consisting of a metal material and a ceramic material.

Examples of the metal material include single metals, such as gold, silver, copper, nickel, tin, iron, chromium, platinum, palladium, rhodium, iridium, ruthenium, osmium, indium, zinc, molybdenum, manganese, titanium, and aluminum; and alloys containing two or more metals, such as stainless steel and brass.

Examples of the ceramic material include barium titanate, aluminum nitride, boron nitride, aluminum oxide, silicon carbide, and silicon nitride.

Of these, a metal material is preferred from the viewpoint of high thermal conductivity, processability, and flexibility. Among the metal materials, copper (inclusive of oxygen-free copper) and stainless steel are preferred, and from the standpoint that the thermal conductivity is high and that furthermore, the processability is easy, copper is more preferred.

As the resin, the aforementioned resins can be used.

Here, representative examples of the metal material having a high thermal conductivity, which is used in the present invention, are exemplified below.

Oxygen-Free Copper

In general, oxygen-free copper (OFC) refers to high-purity copper of 99.95% (3N) or more, which does not contain an oxide. According to the Japanese Industrial Standards, oxygen-free copper (JIS H3100, C1020) and oxygen-free copper for electron tube (JIS H3510, C1011) are prescribed.

Stainless Steel (JIS)

SUS304: 18Cr-8Ni (containing 18% of Cr and 8% of Ni)

SUS316: 18Cr-12Ni (stainless steel containing 18% of Cr and 12% of Ni, and molybdenum (Mo))

The thermal conductivity of the heat dissipation layer is preferably 5 to 500 W/(m·K), more preferably 12 to 450 W/(m·K), and still more preferably 15 to 420 W/(m·K). When the thermal conductivity of the heat dissipation layer falls within the aforementioned range, the temperature difference can be efficiently given.

The thickness of the heat dissipation layer is preferably 40 to 550 μm, more preferably 60 to 530 μm, and still more preferably 80 to 510 μm. When the thickness of the heat dissipation layer falls within this range, the heat can be selectively dissipated in a specified direction; and the temperature difference can be efficiently given in the in-plane direction of the thermoelectric element layer in which the P-type thermoelectric element layer and the N-type thermoelectric element layer are alternately arranged to be adjacent to each other in the in-plane direction via the electrode and disposed in series.

### <Covering Layer>

Preferably, the thermoelectric conversion module of the present invention includes the covering layer on at least one face of the thermoelectric element layer. Though the covering layer is not particularly limited, examples thereof include a sealing layer and a gas barrier layer. In this specification, the covering layer is distinguished from the insulating layer covering the heat dissipation layer.

### <Sealing Layer>

The thermoelectric conversion module of the present invention may include a sealing layer as the covering layer. The sealing layer is able to effectively suppress transmission of a water vapor in the air.

The sealing layer may be laminated on the thermoelectric element layer either directly or via a substrate, or may be laminated via a gas barrier layer or an insulating layer as mentioned later.

A main component constituting the sealing layer which is used in the present invention is preferably a polyolefin-based resin, an epoxy-based resin, or an acrylic resin.

Preferably, the sealing layer is composed of a sealant having pressure sensitive adhesiveness (hereinafter sometimes referred to as “sealant composition”). In this specification, the matter that the sealing layer has pressure sensitive adhesiveness means that the sealant has pressure sensitive adhesiveness or adhesiveness, or has pressure sensitive adhesiveness in a normal state and then bonds upon addition of energy to cause hardening. By using the sealing layer, lamination on the thermoelectric element layer can be easily performed. In addition, sticking to the insulating layer, the heat dissipation layer, a gas barrier layer as mentioned later, or the like also becomes easy.

Though the polyolefin-based resin is not particularly limited, examples thereof include a diene-based rubber having a carboxylic acid-based functional group (hereinafter sometimes referred to as “diene-based rubber”), or a diene-based rubber having a carboxylic acid-based functional group and a rubber-based polymer not having a carboxylic acid-based functional group (hereinafter sometimes referred to as “rubber-based polymer”).

The diene-based rubber is a diene-based rubber constituted of a polymer having a carboxylic acid-based functional group at the terminal of the main chain and/or in the side chain. Here, the “carboxylic acid-based functional group” refers to “a carboxy group or a carboxylic anhydride group”. In addition, the “diene-based rubber” refers to “a rubber-like polymer having a double bond in the polymer main chain”.

The diene-based rubber is not particularly limited so long as it is a diene-based rubber having a carboxylic acid-based functional group.

Examples of the diene-based rubber include a carboxylic acid-based functional group-containing polybutadiene-based rubber, a carboxylic acid-based functional group-containing polyisoprene-based rubber, a copolymer rubber of butadiene and isoprene containing a carboxylic acid-based functional group, and a copolymer rubber of butadiene and n-butene containing a carboxylic acid-based functional group. Of these, a carboxylic acid-based functional group-containing polyisoprene-based rubber is preferred as the diene-based rubber from the viewpoint that a sealing layer having sufficiently high cohesive strength after crosslinking may be efficiently formed.

The diene-based rubber can be used either alone or in combination of two or more thereof.

The diene-based rubber can be, for example, obtained by a method of performing a copolymerization reaction using a monomer having a carboxy group; and a method of adding maleic anhydride to a polymer, such as polybutadiene, as described in JP 2009-29976 A.

The blending amount of the diene-based rubber is preferably 0.5 to 95.5% by mass, more preferably 1.0 to 50% by mass, and still more preferably 2.0 to 20% by mass in the sealant composition. When the blending amount of the diene-based rubber is 0.5% by mass or more in the sealant composition, the sealing layer having sufficient cohesive strength can be efficiently formed. In addition, by not excessively increasing the blending amount of the diene-based rubber, the sealing layer having sufficient pressure sensitive adhesive strength can be efficiently formed.

A crosslinking agent which is used in the present invention is a compound capable of reacting with the carboxylic acid-based functional group of the diene-based rubber, to form a crosslinked structure.

Examples of the crosslinking agent include an isocyanate-based crosslinking agent, an epoxy-based crosslinking agent, an aziridine-based crosslinking agent, and a metal chelate-based crosslinking agent.

The rubber-based polymer refers to a “resin exhibiting rubber elasticity at 25° C”. Preferably, the rubber-based polymer is a rubber having a polymethylene type saturated main chain or a rubber having an unsaturated carbon bond in the main chain.

Specifically, examples of such a rubber-based polymer include a homopolymer of isobutylene (polyisobutylene, IM), a copolymer of isobutylene and n-butene, a natural rubber (NR), a homopolymer of butadiene (butadiene rubber, BR), a homopolymer of chloroprene (chloroprene rubber, CR), a homopolymer of isoprene (isoprene rubber, IR), a copolymer of isobutylene and butadiene, a copolymer of isobutylene and isoprene (butyl rubber, IIR), a halogenated butyl rubber, a copolymer of styrene and 1,3-butadiene (styrene-butadiene rubber, SBR), a copolymer of acrylonitrile and 1,3-butadiene (nitrile rubber), a styrene-1,3-butadiene-styrene block copolymer (SBS), a styrene-isoprene-styrene block copolymer (SIS), and an ethylene-propylene-non-conjugated diene ternary copolymer. Of these, an isobutylene-based polymer, such as a homopolymer of isobutylene, a copolymer of isobutylene and n-butene, a copolymer of isobutylene and butadiene, and a copolymer of isobutylene and isoprene, is preferred, and a copolymer of isobutylene and isoprene is more preferred from the viewpoint that not only it itself has an excellent water barrier capability, but also it is readily mixed with the diene-based rubber (A) and is easy to form a uniform sealing layer.

In the case of blending the rubber-based polymer, its blending amount is preferably 0.1% by mass to 99.5% by mass, more preferably 10 to 99.5% by mass, still more preferably 50 to 99.0% by mass, and especially preferably 80 to 98.0% by mass in the sealant composition.

Though the epoxy-based resin is not particularly limited, it is preferably a polyfunctional epoxy compound having at least two epoxy groups in a molecule thereof.

Examples of the epoxy compound having at least two epoxy groups include bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, a novolak type epoxy resin (for example, a phenol⋅novolak type epoxy resin, a cresol⋅novolak type epoxy resin, and a brominated phenol⋅novolak type epoxy resin), hydrogenated bisphenol A diglycidyl ether, hydrogenated bisphenol F diglycidyl ether, hydrogenated bisphenol S diglycidyl ether, pentaerythritol polyglycidyl ether, 1,6-hexanediol diglycidyl ether, diglycidyl hexahydrophthalate, neopentyl glycol diglycidyl ether, trimethylolpropane polyglycidyl ether, 2,2-bis(3-glycidyl-4-glycidyloxyphenyl)propane, and dimethylol tricyclodecane diglycidyl ether.

These polyfunctional epoxy compounds can be used either alone or in combination of two or more thereof.

A lower limit of the molecular weight of the polyfunctional epoxy compound is preferably 700 or more, and more preferably 1,200 or more. An upper limit of the molecular weight of the polyfunctional epoxy compound is preferably 5,000 or less, and more preferably 4,500 or less.

The epoxy equivalent of the polyfunctional epoxy compound is preferably 100 g/eq or more and 500 g/eq or less, and more preferably 150 g/eq or more and 300 g/eq or less.

The content of the epoxy-based resin in the sealant composition is preferably 10 to 50% by mass, and more preferably 10 to 40% by mass.

Though the acrylic resin is not particularly limited, a (meth)acrylic acid ester-based copolymer is preferred.

As this (meth)acrylic acid ester-based copolymer, copolymers of an alkyl (meth)acrylate in which the alkyl group of the ester moiety has 1 to 18 carbon atoms and a crosslinkable functional group-containing ethylenic monomer or other monomer, which is used as the need arises, can be preferably exemplified. Examples of the alkyl (meth)acrylate in which the alkyl group of the ester moiety has 1 to 18 carbon atoms include methyl acrylate, methyl methacrylate, ethyl acrylate, ethyl methacrylate, propyl acrylate, propyl methacrylate, isopropyl acrylate, isopropyl methacrylate, n-butyl acrylate, n-butyl methacrylate, isobutyl acrylate, isobutyl methacrylate, n-hexyl acrylate, n-hexyl methacrylate, 2-ethylhexyl acrylate, 2-ethylhexyl methacrylate, lauryl acrylate, lauryl methacrylate, stearyl acrylate, and stearyl methacrylate. These may be used alone or may be used in combination of two or more thereof.

The crosslinkable functional group-containing ethylenic monomer which is used, as the need arises is an ethylenic monomer having a functional group, such as a hydroxy group, a carboxy group, an amino group, a substituted amino group, and an epoxy group, in a molecule thereof, and preferably, a hydroxy group-containing ethylenically unsaturated compound or carboxy group-containing ethylenically unsaturated compound is used. Specific examples of such a crosslinkable functional group-containing ethylenic monomer include hydroxy group-containing (meth)acrylates, such as 2-hydroxyethyl acrylate, 2-hydroxyethyl methacrylate, 2-hydroxypropyl acrylate, 2-hydroxypropyl methacrylate, 2-hydroxybutyl acrylate, 2-hydroxybutyl methacrylate, 4-hydroxybutyl acrylate, and 4-hydroxybutyl methacrylate; and carboxy group-containing ethylenically unsaturated compounds, such as acrylic acid, methacrylic acid, crotonic acid, maleic acid, itaconic acid, and citraconic acid. The aforementioned crosslinkable functional group-containing ethylenic monomers may be used either alone or in combination of two or more thereof.

Examples of the other monomer which is used, as the need arises include (meth)acrylic acid esters having an alicyclic structure, such as cyclohexyl acrylate and isobornyl acrylate; vinyl esters, such as vinyl acetate and vinyl propionate; olefins, such as ethylene, propylene, and isobutylene; halogenated olefins, such as vinyl chloride and vinylidene chloride; styrene-based monomers, such as styrene and α-methylstyrene; diene-based monomers, such as butadiene, isoprene, and chloroprene; nitrile-based monomers, such as acrylonitrile and methacrylonitrile; and N,N-dialkyl-substituted acrylamides, such as N,N-dimethylacrylamide and N,N-dimethylmethacrylamide. These may be used alone or may be used in combination of two or more thereof.

The foregoing (meth)acrylic acid ester and crosslinkable functional group-containing ethylenic monomer or other monomer, which is used as the need arises, are used in predetermined ratios, respectively and copolymerized with each other by adopting a conventionally known method, thereby producing a (meth)acrylic acid ester-based polymer having a weight average molecular weight of preferably about 300,000 to 1,500,000, and more preferably about 350,000 to 1,300,000.

The aforementioned weight average molecular weight is a value measured by the gel permeation chromatography (GPC) as expressed in terms of standard polystyrene.

As the crosslinking agent which is used, as the need arises, an arbitrary material can be properly selected and used among those which are customarily used as a crosslinking agent in conventional acrylic resins. Examples of such a crosslinking agent include a polyisocyanate compound, an epoxy compound, a melamine resin, a urea resin, a dialdehyde, a methylol polymer, an aziridine-based copolymer, a metal chelate compound, a metal alkoxide, and a metal salt. In the case where the aforementioned (meth)acrylic acid ester-based compound has a hydroxy group as the crosslinkable functional group, a polyisocyanate compound is preferred, whereas in the case where the (meth)acrylic acid ester-based copolymer has a carboxy group, a metal chelate compound or an epoxy compound is preferred.

The content of the acrylic resin in the sealant composition is preferably 30 to 95% by mass, and more preferably 40 to 90% by mass.

In the sealant constituting the sealing layer, other component may be contained within a range where the effects of the present invention are not impaired. Examples of the other component which may be contained in the sealant include a high thermal conductive material, a flame retardant, a tackifier, a UV absorber, an antioxidant, an antiseptic, an antifungal agent, a plasticizer, an anti-foaming agent, and a wettability controlling agent.

The sealing layer may be either a single layer or a laminate of two or more layers. In the case of a laminate of two or more layers, those layers may be the same as or different from each other.

The thickness of the sealing layer is preferably 0.5 to 100 μm, more preferably 3 to 50 μm, and still more preferably 5 to 30 μm. When the thickness of the sealing layer falls within this range, in the case where the sealing layer is laminated on the face of the thermoelectric element layer of the thermoelectric conversion module, a water vapor transmission rate can be suppressed, and the durability of the thermoelectric conversion module is improved.

Furthermore, as mentioned above, it is preferred that the thermoelectric element layer comes into direct contact with the sealing layer. When the thermoelectric element layer comes into direct contact with the sealing layer, the water vapor in the air does not directly exist between the thermoelectric element layer and the sealing layer, and therefore, the interpenetration of the thermoelectric element layer into the water vapor is suppressed, and the sealing properties of the sealing layer are improved.

### <Gas Barrier Layer>

The thermoelectric conversion module of the present invention may further include a gas barrier layer as the covering layer. The gas barrier layer is able to effectively suppress the transmission of the water vapor in the air.

The gas barrier layer may be laminated directly on the thermoelectric element layer; may be constituted of a layer containing a main component as mentioned later on a base material, either one face of which is laminated directly on the thermoelectric element layer; or may be laminated via the sealing layer and the insulating layer.

The gas barrier layer which is used in the present invention is composed of, as a main component, at least one selected from the group consisting of a metal, an inorganic compound, and a polymer compound. The durability of the thermoelectric conversion module can be improved by the gas barrier layer.

As the base material, one having flexibility is used, and for example, the resin which is used for the aforementioned insulating layer can be used. In addition, the preferred resin is also the same.

Examples of the metal include aluminum, magnesium, nickel, zinc, gold, silver, copper, and tin, and it is preferred that such a metal is used as a deposited film. Of these, aluminum and nickel are preferred from the viewpoint of productivity, cost, and gas barrier properties. In addition, these can be used either alone or in combination of two or more thereof inclusive of an alloy. The deposited film may be typically formed by adopting a deposition method, such as a vacuum deposition method and an ion plating method, or may be formed by a sputtering method other than the deposition method, such as a DC sputtering method and a magnetron sputtering method, or other dry method, such as a plasma CVD method. Since the metal deposited film or the like has electrical conductivity, it is typically laminated on the thermoelectric element layer via the aforementioned base material or the like.

Examples of the inorganic compound include an inorganic oxide (MOₓ), an inorganic nitride (MNy), an inorganic carbide (MC_{z}), an inorganic oxycarbide (MOₓC_{z}), an inorganic nitride carbide (MN_{y}C_{z}), an inorganic oxynitride (MOₓN_{y}), and an inorganic oxynitride carbide (MOₓN_{y}C_{z}). Here, x, y, and z each represent a composition ratio of the respective compound. Examples of M include metal elements, such as silicon, zinc, aluminum, magnesium, indium, calcium, zirconium, titanium, boron, hafnium, and barium. M may be a single element or may be two or more elements. Examples of the respective inorganic compound include oxides, such as silicon oxide, zinc oxide, aluminum oxide, magnesium oxide, indium oxide, calcium oxide, zirconium oxide, titanium oxide, boron oxide, hafnium oxide, and barium oxide; nitrides, such as silicon nitride, aluminum nitride, boron nitride, and magnesium nitride; carbides, such as silicon carbide; and sulfides. In addition, the inorganic compound may also be a complex of two or more materials selected from these inorganic compounds (e.g., an oxynitride, an oxycarbide, a nitride carbide, and an oxynitride carbide). In addition, the inorganic compound may also be a complex containing two or more metal elements, as in SiOZn (also inclusive of an oxynitride, an oxycarbide, a nitride carbide, and an oxynitride carbide). Though it is preferred that such a material is used as the deposited film, in the case where the material cannot be formed as the deposited film, the film may be formed by a method, such as a DC sputtering method, a magnetron sputtering method, and a plasma CVD method.

M is preferably a metal element, such as silicon, aluminum, and titanium. In particular, the inorganic layer compose of silicon oxide in which M is silicon has high gas barrier properties, and the inorganic layer compose of silicon nitride has higher gas barrier properties. A complex of silicon oxide and silicon nitride (inorganic oxynitride (MOₓN_{y})) is especially preferred, and when the content of silicon nitride is high, the gas barrier properties are improved.

Typically, deposited films composed of an inorganic compound occasionally have insulation properties; however, those having electrical conductivity, such as zinc oxide and indium oxide, are also included. In this case, in the case of laminating such an inorganic compound on the thermoelectric element layer, it is laminated via the aforementioned base material, or is used within a range where it does not affect the performance of the thermoelectric conversion module.

Examples of the polymer compound include a silicon-containing polymer compound, such as a polyorganosiloxane and a polysilazane-based compound, a polyimide, a polyamide, a polyamide-imide, a polyphenylene ether, a polyetherketone, a polyetheretherketone, a polyolefin, and a polyester. These polymer compounds can be used either alone or in combination of two or more thereof.

Of these, a silicon-containing polymer compound is preferred as the polymer compound having gas barrier properties. Preferred examples of the silicon-containing polymer compound include a polysilazane-based compound, a polycarbosilane-based compound, a polysilane-based compound, and a polyorganosiloxane-based compound. Of these, a polysilazane-based compound is more preferred from the viewpoint that the barrier layer having excellent gas barrier properties can be formed.

A deposited film composed of an inorganic compound, or a silicon oxynitride composed of a layer having, as main constituent atoms, oxygen, nitrogen, and silicon, which is formed by subjecting a layer containing a polysilazane-based compound to a modification treatment, is preferably used from the viewpoint that it has interlayer adhesion, gas barrier properties, and flexibility.

The gas barrier layer can be, for example, formed by subjecting a polysilazane compound-containing layer to a plasma ion injection treatment, a plasma treatment, a UV irradiation treatment, a heat treatment, or the like. Examples of the ion which is injected by the plasma ion injection treatment include hydrogen, nitrogen, oxygen, argon, helium, neon, xenon, and krypton.

Examples of a specific treatment method of the plasma ion injection treatment include a method in which ions existing in a plasma generated using an external electric field are injected into the polysilazane compound-containing layer; and a method in which ions existing in a plasma generated only by an electric field due to a negative high-voltage pulse to be impressed to a layer composed of a gas barrier layer-forming material without using an external electric field are injected to the polysilazane compound-containing layer.

The plasma treatment is a method in which a polysilazane compound-containing layer is exposed in a plasma, thereby modifying the layer containing the silicon-containing polymer. For example, the plasma treatment can be, for example, performed according to the method described in JP 2012-106421 A. The UV irradiation treatment is a method in which ultraviolet rays are irradiated on a polysilazane compound-containing layer, thereby modifying the layer containing the silicon-containing polymer. For example, the UV modification treatment can be performed according to the method described in JP 2013-226757 A.

Of these, the ion injection treatment is preferred in view of the fact that the modification can be efficiently achieved to the interior of the polysilazane compound-containing layer without roughening the surface thereof, whereby the gas barrier layer with more excellent gas barrier properties can be formed.

Though the thickness of the layer containing a metal, an inorganic compound, and/or a polymer compound varies with the compound to be used, etc., it is typically 0.01 to 50 μm, preferably 0.03 to 10 μm, more preferably 0.05 to 0.8 μm, and still more preferably 0.10 to 0.6 μm. When the thickness of the layer containing a metal, an inorganic compound, and/or a resin falls within this range, the water vapor transmission rate can be effectively suppressed.

The thickness of the gas barrier layer including the base material, which is composed of the aforementioned metal, inorganic compound, and/or polymer compound is preferably 10 to 80 μm, more preferably 15 to 50 μm, and still more preferably 20 to 40 μm. When the thickness of the gas barrier layer falls within this range, not only the excellent gas barrier properties are obtained, but also both the flexibility and the covering film strength can be made compatible with each other.

The gas barrier layer may be either a single layer or a laminate of two or more layers. In the case of a laminate of two or more layers, those layers may be the same as or different from each other.

### <Substrate>

Though the substrate of the thermoelectric conversion module which is used in the present invention is not particularly limited, it is preferred to use a film substrate which neither lowers the electrical conductivity of the thermoelectric element layer nor affects the increase of the thermal conductivity. Above all, a polyimide film, a polyamide film, a polyether imide film, a polyaramid film, and a polyamide-imide film are preferred from the standpoint that they are excellent in flexibility, even in the case where a thin film formed of a thermoelectric semiconductor composition as mentioned later is subjected to an annealing treatment, the performance of the thermoelectric element layer can be maintained without causing thermal deformation of the substrate, and the heat resistance and the dimensional stability are high; and furthermore, a polyimide film is especially preferred from the standpoint that it is high in versatility.

The thickness of the substrate is preferably 1 to 1,000 μm, more preferably 10 to 500 μm, and still more preferably 20 to 100 μm from the viewpoint of flexibility, heat resistance, and dimensional stability.

As for the aforementioned film, its decomposition temperature is preferably 300° C. or higher.

### <Electrode Layer>

The electrode layer which is used in the present invention is provided for the purpose of electrically connecting a P-type thermoelectric element layer and an N-type thermoelectric element layer constituting the thermoelectric element layer as mentioned later with each other. Examples of an electrode material include gold, silver, nickel, copper, and an alloy thereof.

The thickness of the electrode layer is preferably 10 nm to 200 μm, more preferably 30 nm to 150 μm, and still more preferably 50 nm to 120 μm. When the thickness of the electrode layer falls within the aforementioned range, the electrical conductivity is high, and the resistance is low, so that a total electrical resistance value of the thermoelectric element layer is controlled to a low level. In addition, a sufficient strength as the electrode is obtained.

### <Thermoelectric Element Layer>

As for the thermoelectric element layer of the thermoelectric conversion module which is used in the present invention, as mentioned above, the thermoelectric element layer is a thermoelectric element layer including a P-type thermoelectric element layer and an N-type thermoelectric element layer, in which the P-type thermoelectric element layer and the N-type thermoelectric element layer are alternately arranged to be adjacent to each other in the in-plane direction and disposed in series, and are configured so as to be electrically connected with each other in series. Furthermore, the connection between the P-type thermoelectric element layer and the N-type thermoelectric element layer may be made via the aforementioned electrode layer formed of a metal material having high electrical conductivity or other material from the viewpoint of stability of the connection and thermoelectric performance.

Preferably, the thermoelectric element layer which is used in the present invention is a layer formed of a thermoelectric semiconductor composition containing thermoelectric semiconductor fine particles, a heat-resistant resin, and one or both of an ionic liquid and an inorganic ionic compound on the substrate.

### (Thermoelectric Semiconductor Fine Particles)

As for the thermoelectric semiconductor fine particles which are used for the thermoelectric element layer, it is preferred that a thermoelectric semiconductor material is pulverized to a predetermined size by a pulverizer or the like.

A material constituting each of the P-type thermoelectric element layer and the N-type thermoelectric element layer, which is used in the present invention, is not particularly limited so long as it is a material capable of generating a thermoelectromotive force by giving a temperature difference. Examples thereof include bismuth-tellurium-based thermoelectric semiconductor materials, such as P-type bismuth telluride and N-type bismuth telluride; telluride-based thermoelectric semiconductor materials, such as GeTe and PbTe; antimony-tellurium-based thermoelectric semiconductor materials; zinc-antimony-based thermoelectric semiconductor materials, such as ZnSb, Zn₃Sb₂, and Zn₄Sb₃; silicon-germanium-based thermoelectric semiconductor materials, such as SiGe; bismuth-selenide-based thermoelectric semiconductor materials, such as Bi₂Se₃; silicide -based thermoelectric semiconductor materials, such as β-FeSi₂, CrSi₂, MnSi_{1.73}, and Mg₂Si; oxide-based thermoelectric semiconductor materials; whistler materials, such as FeVAl, FeVAlSi, and FeVTiAl; and sulfide-based thermoelectric semiconductor materials, such as TiS₂.

Of these, a bismuth-tellurium-based thermoelectric semiconductor material, such as P-type bismuth telluride or N-type bismuth telluride, is preferred as the thermoelectric semiconductor material which is used in the present invention.

The P-type bismuth telluride is one in which the carrier is a hole, and the Seebeck coefficient is a positive value, and for example, one represented by BixTe₃Sb_{2·X} is preferably used. In this case, X is preferably 0<X≤0.8, and more preferably 0.4≤X≤0.6. When X is more than 0 and 0.8 or less, the Seebeck coefficient and the electrical conductivity become large, and the characteristics as a p-type thermoelectric conversion material are maintained, and hence, such is preferred.

The N-type bismuth telluride is one in which the carrier is an electron, and the Seebeck coefficient is a negative value, and for example, one represented by Bi₂Te_{3·Y}Se_{Y} is preferably used. In this case, Y is preferably 0≤Y≤3 (when Y=0, Bi₂Te₃), and more preferably 0<Y≤2.7. When Y is 0 or more and 3 or less, the Seebeck coefficient and the electrical conductivity become large, and the characteristics as an n-type thermoelectric conversion material are maintained, and hence, such is preferred.

The blending amount of the thermoelectric semiconductor fine particles in the thermoelectric semiconductor composition is preferably 30 to 99% by mass, more preferably 50 to 96% by mass, and still more preferably 70 to 95% by mass. When the blending amount of the thermoelectric semiconductor fine particles falls within the aforementioned range, the Seebeck coefficient (an absolute value of the Peltier coefficient) is large, the lowering of the electrical conductivity is suppressed, and only the thermal conductivity is lowered, and therefore, a film not only exhibiting a high thermoelectric performance but also having sufficient film strength and flexibility is obtained. Thus, such is preferred.

The average particle diameter of the thermoelectric semiconductor fine particles is preferably 10 nm or 200 μm, more preferably 10 nm to 30 μm, still more preferably 50 nm to 10 μm, and especially preferably 1 to 6 μm. When the average particle diameter of the thermoelectric semiconductor fine particles falls within the aforementioned range, the uniform dispersion becomes easy, and the electrical conductivity can be enhanced.

A method of pulverizing the thermoelectric semiconductor material to obtain thermoelectric semiconductor fine particles is not particularly limited, and the thermoelectric semiconductor material may be pulverized to a predetermined size by a known pulverizer, such as a jet mill, a ball mill, a beads mill, a colloid mill, a conical mill, a disk mill, an edge mill, a grinding mill, a hammer mill, a pellet mill, a Willy mill, and a roller mill.

The average particle diameter of the thermoelectric semiconductor fine particles is one obtained through measurement with a laser diffraction particle size analyzer (1064 Model, manufactured by CILAS), and a median value of the particle size distribution was taken.

The thermoelectric semiconductor fine particles are preferably ones having been subjected to an annealing treatment (hereinafter sometimes referred to as “annealing treatment A”). As for the thermoelectric semiconductor fine particles, by performing the annealing treatment A, the crystallinity is improved, and furthermore, the surface oxide films of the thermoelectric semiconductor fine particles are removed, and therefore, the Seebeck coefficient (an absolute value of the Peltier coefficient) of the thermoelectric conversion material increases, whereby a figure of merit can be more improved. Though the annealing treatment A is not particularly limited, the annealing treatment A is preferably performed in an inert gas atmosphere of nitrogen, argon, or the like, in which the gas flow rate is controlled, or in a reducing gas atmosphere of hydrogen or the like, in which the gas flow rate is similarly controlled, or in a vacuum condition, such that the thermoelectric semiconductor fine particles are not adversely affected before preparation of the thermoelectric semiconductor composition. The annealing treatment A is more preferably performed in a mixed gas atmosphere of an inert gas and a reducing gas. Though a specific temperature condition depends upon the thermoelectric semiconductor fine particles to be used, typically, it is preferred to perform the annealing treatment A at a temperature of not higher than the melting point of the fine particles and at 100 to 1,500° C. for several minutes to several tens hours.

### (Heat-Resistant Resin)

The heat-resistant resin which is used in the present invention is one acting as a binder between the thermoelectric semiconductor fine particles and enhancing the flexibility of the thermoelectric conversion material. Though the heat-resistant resin is not particularly limited, a heat-resistant resin in which various physical properties as a resin, such as mechanical strength and thermal conductivity, are maintained without being impaired on the occasion of subjecting the thermoelectric semiconductor fine particles to crystal growth by an annealing treatment of a thin film formed of the thermoelectric semiconductor composition, or the like, is used.

Examples of the heat-resistant resin include a polyamide resin, a polyamide-imide resin, a polyimide resin, a polyether imide resin, a polybenzoxazole resin, a polybenzimidazole resin, an epoxy resin, and a copolymer having a chemical structure of such a resin. The heat-resistant resin may be used either alone or in combination of two or more thereof. Of these, a polyamide resin, a polyamide-imide resin, a polyimide resin, and an epoxy resin are preferred from the standpoint that not only the heat resistance is higher, but also the crystal growth of the thermoelectric semiconductor fine particles in the thin film is not adversely affected; and a polyamide resin, a polyamide-imide resin, and a polyimide resin are more preferred from the standpoint that the flexibility is excellent. In the case of using a polyimide film as the aforementioned support, a polyimide resin is more preferred as the heat-resistant resin from the standpoint of adhesion to the polyimide film. In the present invention, the polyimide resin is a generic term for a polyimide and a precursor thereof.

Preferably, the heat-resistant resin has a decomposition temperature of 300° C. or higher. When the decomposition temperature falls within the aforementioned range, even in the case of subjecting the thin film formed of the thermoelectric semiconductor composition to an annealing treatment as mentioned later, the flexibility of the thermoelectric conversion material can be maintained without losing the function as the binder.

As for the heat-resistant resin, its mass reduction rate at 300° C. by the thermogravimetry (TG) is preferably 10% or less, more preferably 5% or less, and still more preferably 1% or less. When the mass reduction rate falls within the aforementioned range, even in the case of subjecting the thin film formed of the thermoelectric semiconductor composition to an annealing treatment as mentioned later, the flexibility of the thermoelectric conversion material can be maintained without losing the function as the binder.

The blending amount of the heat-resistant resin in the thermoelectric semiconductor composition is preferably 0.1 to 40% by mass, more preferably 0.5 to 20% by mass, and still more preferably 1 to 20% by mass. When the blending amount of the heat-resistant resin falls within the aforementioned range, a film in which both high thermoelectric performance and film strength are compatible with each other is obtained.

### (Ionic Liquid)

The ionic liquid which is used in the present invention is a molten salt composed of a combination of a cation and an anion and refers to a salt capable of existing as a liquid in a broad temperature region of −50 to 500° C. The ionic liquid has such characteristic features that it has an extremely low vapor pressure and is nonvolatile; it has excellent heat stability and electrochemical stability; its viscosity is low; and its ionic conductivity is high, and therefore, the ionic liquid is able to effectively suppress a reduction of the electrical conductivity between the thermoelectric semiconductor fine particles as an electrical conductive assistant. In addition, the ionic liquid exhibits high polarity based on the aprotic ionic structure thereof and is excellent in compatibility with a heat-resistant resin, and therefore, the ionic liquid can make the thermoelectric conversion material have a uniform electrical conductivity.

As the ionic liquid, any known materials or commercially available products can be used. Examples thereof include those constituted of a cation component, such as a nitrogen-containing cyclic cation compound, e.g., pyridinium, pyrimidinium, pyrazolium, pyrrolidinium, piperidinium, and imidazolium, and a derivative thereof, a tetraalkylammonium type amine-based cation and a derivative thereof, a phosphine-based cation, e.g., phosphonium, a trialkylsulfonium, and a tetraalkylphosphonium, and a derivative thereof, and a lithium cation and a derivative thereof; and an anion component, such as Cl⁻, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, and (CF₃SO₂)(CF₃CO)N⁻.

Among the aforementioned ionic liquids, it is preferred that the cation component of the ionic liquid contains at least one selected from a pyridinium cation and a derivative thereof, and an imidazolium cation and a derivative thereof, from the viewpoint of securing the high-temperature stability and the compatibility between the thermoelectric semiconductor fine particles and the resin as well as from the viewpoint of suppressing a reduction in the electrical conductivity between thermoelectric semiconductor fine particles, and so on.

Specific examples of the ionic liquid in which the cation component contains any of a pyridinium cation and a derivative thereof include 1-butyl-3-(2-hydroxyethyl)pyridinium bromide, 4-methyl-butylpyridinium chloride, 3-methyl-butylpyridinium chloride, 4-methyl-hexylpyridinium chloride, 3-methyl-hexylpyridinium chloride, 4-methyl-octylpyridinium chloride, 3-methyl-octylpyridinium chloride, 3,4-dimethyl-butylpyridinium chloride, 3,5-dimethyl-butylpyridinium chloride, 4-methyl-butylpyridinium tetrafluoroborate, 4-methyl-butylpyridinium hexafluorophosphate, 1-butyl-4-methylpyridinium bromide, and 1-butyl-4-methylpyridinium hexafluorophosphate. Of these, 1-butyl-3-(2-hydroxyethyl)pyridinium bromide, 1-butyl-4-methylpyridinium bromide, and 1-butyl-4-methylpyridinium hexafluorophosphate are preferred.

Specific examples of the ionic liquid in which the cation component contains any of an imidazolium cation and a derivative thereof include [1-butyl -3-(2-hydroxyethyl)imidazolium bromide], [1-butyl-3-(2-hydroxyethyl)imidazolium tetrafluoroborate], 1-ethyl-3-methylimidazolium chloride, 1-ethyl-3-methylimidazolium bromide, 1-butyl-3-methylimidazolium chloride, 1-hexyl-3-methylimidazolium chloride, 1-octyl-3-methylimidazolium chloride, 1-decyl-3-methylimidazolium chloride, 1-decyl-3-methylimidazolium bromide, 1-dodecyl-3-methylimidazolium chloride, 1-tetradecyl-3-methylimidazolium chloride, 1-ethyl-3-methylimidazolium tetrafluoroborate, 1-butyl-3-methylimidazolium tetrafluoroborate, 1-hexyl-3-methylimidazolium tetrafluoroborate, 1-ethyl-3-methylimidazolium hexafluorophosphate, 1-butyl-3-methylimidazolium hexafluorophosphate, 1-methyl-3-butylimidazolium methyl sulfate, and 1,3-dibutylimidazolium methyl sulfate. Of these, [1-butyl-3-(2-hydroxyethyl)imidazolium bromide] and [1-butyl-3-(2-hydroxyethyl)imidazolium tetrafluoroborate] are preferred.

Preferably, the aforementioned ionic liquid has an electrical conductivity of 10⁻⁷ S/cm or more. When the ionic conductivity falls within the aforementioned range, a reduction of the electrical conductivity between the thermoelectric semiconductor fine particles can be effectively suppressed as the electrical conductive assistant.

Preferably, the ionic liquid has a decomposition temperature of 300° C. or higher. When the decomposition temperature falls within the aforementioned range, even in the case of subjecting the thin film formed of the thermoelectric semiconductor composition to an annealing treatment as mentioned later, the effect as the electrical conductive assistant can be maintained.

As for the ionic liquid, its mass reduction rate at 300° C. by the thermogravimetry (TG) is preferably 10% or less, more preferably 5% or less, and still more preferably 1% or less. When the mass reduction rate falls within the aforementioned range, even in the case of subjecting the thin film formed of the thermoelectric semiconductor composition to an annealing treatment as mentioned later, the effect as the electrical conductive assistant can be maintained.

The blending amount of the ionic liquid in the thermoelectric semiconductor composition is preferably 0.01 to 50% by mass, more preferably 0.5 to 30% by mass, and still more preferably 1.0 to 20% by mass. When the blending amount of the ionic liquid falls within the aforementioned range, a lowering of the electrical conductivity is effectively suppressed, and a film having a high thermoelectric performance is obtained.

### (Inorganic Ionic Compound)

The inorganic ionic compound which is used in the present invention is a compound constituted of at least a cation and an anion. The inorganic ionic compound exists as a solid in a broad temperature region of 400 to 900° C. and has such a characteristic feature that its ionic conductivity is high, and therefore, it is able to suppress a reduction of the electrical conductivity between the thermoelectric semiconductor fine particles as the electrical conductive assistant.

A metal cation is used as the cation.

Examples of the metal cation include an alkali metal cation, an alkaline earth metal cation, a typical metal cation, and a transition metal cation, with an alkali metal cation or an alkaline earth cation being preferred.

Examples of the alkali metal cation include Li⁺, Na⁺, K⁺, Rb⁺, Cs⁺, and Fr⁺.

Examples of the alkaline earth metal cation include Mg²⁺, Ca²⁺, Sr²⁺, and Ba²⁺.

Examples of the anion include F⁻, Cl⁻, Br⁻, I⁻, OH⁻, CN⁻, NO₃⁻, NO₂⁻, ClO⁻, ClO₂⁻, ClO₃⁻, ClO₄⁻, CrO₄²⁻, HSO₄⁻, SCN⁻, BF₄⁻, and PF₆⁻.

As the inorganic ionic compound, any known materials or commercially available products can be used. Examples thereof include those constituted of a cation component, such as a potassium cation, a sodium cation, and a lithium cation; and an anion component, such as a chloride ion, e.g., Cl⁻, AlCl₄⁻, Al₂Cl₇⁻, and ClO₄⁻, a bromide ion, e.g., Br⁻, an iodide ion, such as I⁻, a fluoride ion, e.g., BF₄⁻ and PF₆⁻, a halide anion, e.g., F(HF)ₙ⁻, NO₃⁻, OH⁻, and CN⁻.

Among the aforementioned inorganic ionic compounds, it is preferred that the cation component of the inorganic ionic compound contains at least one selected from potassium, sodium, and lithium from the viewpoint of securing the high-temperature stability and the compatibility between the thermoelectric semiconductor fine particles and the resin as well as from the viewpoint of suppressing a lowering of the electrical conductivity between thermoelectric semiconductor fine particles, and so on. In addition, the anion component of the inorganic ionic compound contains preferably a halide anion, and more preferably at least one selected from Cl⁻, Br⁻, and I⁻.

Specific examples of the inorganic ionic compound in which the cation component contains a potassium cation include KBr, KI, KCl, KF, KOH, and K₂CO₃. Of these, KBr and KI are preferred.

Specific examples of the inorganic ionic compound in which the cation component contains a sodium cation include NaBr, NaI, NaOH, NaF, and Na₂CO₃. Of these, NaBr and NaI are preferred.

Specific examples of the inorganic ionic compound in which the cation component contains a lithium cation include LiF, LiOH, and LiNO₃. Of these, LiF and LiOH are preferred.

The aforementioned inorganic ionic compound has an electrical conductivity of preferably 10⁻⁷ S/cm or more, and more preferably 10⁻⁶ S/cm or more. When the electrical conductivity falls within the aforementioned range, a reduction of the electrical conductivity between the thermoelectric semiconductor fine particles can be effectively suppressed as the electrical conductive assistant.

Preferably, the inorganic ionic compound has a decomposition temperature of 400° C. or higher. When the decomposition temperature falls within the aforementioned range, even in the case of subjecting the thin film formed of the thermoelectric semiconductor composition to an annealing treatment as mentioned later, the effect as the electrical conductive assistant can be maintained.

As for the inorganic ionic compound, its mass reduction rate at 400° C. by the thermogravimetry (TG) is preferably 10% or less, more preferably 5% or less, and still more preferably 1% or less. When the mass reduction rate falls within the aforementioned range, even in the case of subjecting the thin film formed of the thermoelectric semiconductor composition to an annealing treatment as mentioned later, the effect as the electrical conductive assistant can be maintained.

The blending amount of the inorganic ionic compound in the thermoelectric semiconductor composition is preferably 0.01 to 50% by mass, more preferably 0.5 to 30% by mass, and still more preferably 1.0 to 10% by mass. When the blending amount of the inorganic ionic compound falls within the aforementioned range, a lowering of the electrical conductivity can be effectively suppressed, and as a result, a film having an improved thermoelectric performance is obtained.

In the case of using a combination of the inorganic ionic compound and the ionic liquid, the total amount of contents of the inorganic ionic compound and the ionic liquid in the thermoelectric semiconductor composition is preferably 0.01 to 50% by mass, more preferably 0.5 to 30% by mass, and still more preferably 1.0 to 10% by mass.

The thickness of the thermoelectric element layer composed of the P-type thermoelectric element layer and the N-type thermoelectric element layer is not particularly limited, and it may be either identical or different (a difference of level in a connection part is generated). From the viewpoint of flexibility and material costs, the thickness of each of the P-type thermoelectric element layer and the N-type thermoelectric element layer is preferably 0.1 to 100 μm, and more preferably 1 to 50 μm.

### [Production Method of Thermoelectric Conversion Module]

The production method of the thermoelectric conversion module of the present invention is a method of producing a thermoelectric convention module, including a step of forming the thermoelectric element layer; a step of forming the insulating layer; and a step of forming the heat dissipation layer, wherein the insulating layer has an elastic modulus at 23° C. of 0.1 to 500 GPa.

The steps which are included in the present invention are hereunder successively described.

### <Thermoelectric Element Layer-Forming Step>

The production process of the thermoelectric conversion module includes a thermoelectric element layer-forming step of forming a thermoelectric element layer. Preferably, the thermoelectric element layer which is used in the present invention is formed of the aforementioned thermoelectric semiconductor composition on one face of the aforementioned substrate. Examples of a method of applying the thermoelectric semiconductor composition on the substrate include known methods, such as screen printing, flexographic printing, gravure printing, spin coating, clip coating, die coating, spray coating, bar coating, and doctor blade coating, without being particularly limited. In the case where the coating film is pattern-like formed, screen printing, slot die coating, or the like, capable of forming a pattern in a simplified manner using a screen plate having a desired pattern, is preferably adopted.

Subsequently, the resultant coating film is dried to give a thin film. As the drying method, any conventionally known drying method, such as hot air drying, hot roll drying, and IR radiation, is employable. The heating temperature is typically 80 to 150° C., and though the heating time varies depending upon the heating method, it is typically a few seconds to several tens minutes.

In the case where a solvent is used in preparing the thermoelectric semiconductor composition, the heating temperature is not particularly limited so long as it falls within a range of temperature at which the used solvent can be dried.

After forming the thin film, it is preferred to further perform an annealing treatment (hereinafter sometimes referred to as “annealing treatment B”). By performing the annealing treatment B, not only the thermoelectric performance can be stabilized, but also the thermoelectric semiconductor fine particles in the thin film can be subjected to crystal growth, and the thermoelectric performance can be more improved. Though the annealing treatment B is not particularly limited, the annealing treatment B is typically performed in an inert gas atmosphere of nitrogen, argon, or the like, in which the gas flow rate is controlled, in a reducing gas atmosphere, or in a vacuum condition. Though the treatment depends upon the heat-resistant temperatures of the resin and the ionic fluid to be used, or the like, the treatment is performed at 100 to 500° C. for a few minutes to several tens hours.

### <Insulating Layer-Forming Step>

The production process of the thermoelectric conversion module includes an insulating layer-forming step. The insulating layer-forming step is, for example, a step of forming an insulating layer between the thermoelectric element layer and the heat dissipation layer. In addition, a step of covering the heat dissipation layer is also included.

The formation of the insulating layer can be performed by a known method, and for example, the insulating layer may be formed directly on the face of the thermoelectric element layer or may be stuck via an adhesive layer or the like. In addition, the insulating layer may also be formed by sticking an insulating layer having been formed on a release sheet in advance onto the thermoelectric element layer and then transferring the resulting insulating layer onto the thermoelectric element layer. In addition, as for the insulating layer, two or more thereof may be laminated, or a covering layer may be allowed to intervene.

In the case of covering the heat dissipation layer by the insulating layer, a known method can be adopted, and examples thereof include a method of performing covering by a dipping method or the like.

### <Heat Dissipation Layer-Forming Step>

The production process of the thermoelectric conversion module includes a heat dissipation layer-forming step. The heat dissipation layer-forming step is a step of forming a heat dissipation layer on the insulating layer. In the case where the heat dissipation layer is covered by the insulating layer, typically, the heat dissipation layer-forming step is a step of forming a heat dissipation layer on the thermoelectric element layer via the covering layer or the like.

The formation of the heat dissipation layer can be performed by a known method, and for example, the heat dissipation method may be formed directly on the face of the insulating layer or may be formed via the covering layer. The heat dissipation layer may be formed on the substrate directly or via the covering layer.

As mentioned above, the heat dissipation layer which has been processed into a predetermined pattern shape by a known physical treatment or chemical treatment, mainly those in the photolithography method, or a combination thereof may be stuck onto the insulating layer directly or via the covering layer.

### <Covering Layer-Forming Step>

Preferably, the production process of the thermoelectric conversion module includes a covering layer-forming step. The covering layer-forming step is a step of forming the covering layer between the thermoelectric element layer and the heat dissipation layer.

Preferably, the covering layer-forming step includes a sealing layer-forming step. The formation of the sealing layer can be performed by a known method, and for example, the sealing layer may be formed directly on the face of the thermoelectric element layer and/or on the substrate, or the sealing layer may be formed by sticking a sealing layer having been formed on a release sheet in advance onto the thermoelectric element layer and then transferring the sealing layer onto the thermoelectric element layer. In addition, as for the sealing layer, two or more thereof may be laminated, or an insulating layer or other covering layer may be allowed to intervene.

Preferably, the covering layer-forming step includes a gas barrier layer-forming step. The formation of the gas barrier layer can be performed by a known method, and the gas barrier layer may be formed directly on the face of the thermoelectric element layer and/or on the substrate; the gas barrier layer may be formed by sticking a gas barrier layer having been formed on a release sheet in advance onto the thermoelectric element layer and then transferring the gas barrier layer onto the thermoelectric element layer; or a base material including the gas barrier layer may be laminated opposing to the thermoelectric element layer. In addition, as for the gas barrier layer, two or more thereof may be laminated, or an insulating layer or other covering layer may be allowed to intervene.

### <Electrode-Forming Step>

Preferably, the production process of the thermoelectric conversion module further includes an electrode-forming step of forming an electrode layer on the film substrate by using the aforementioned electrode material and so on. Examples of a method of forming an electrode on the film substrate include a method in which after an electrode layer having no pattern formed thereon is provided on the film substrate, the resultant is processed into a predetermined pattern shape by a known physical treatment or chemical treatment, mainly those in the photolithography method, or a combination thereof; and a method in which a pattern of an electrode layer is directly formed by a screen printing method, an inkjet method, or the like.

Examples of the forming method of an electrode layer having no pattern formed thereon include dry processes, such as PVD (physical vapor deposition method), e.g., a vacuum evaporation method, a sputtering method, and an ion plating method, and CVD (chemical vapor deposition method), e.g., hot CVD and atomic layer deposition (ALD); wet processes, such as various coating or electrodeposition methods, e.g., a dip coating method, a spin coating method, a spray coating method, a gravure coating method, a die coating method, and a doctor blade method; a silver salt method, an electroplating method, an electroless plating method, and lamination of a metal foil, and the forming method is properly selected according to the material of the electrode layer.

In accordance with the production method of the present invention, a thermoelectric conversion module with excellent insulation properties can be produced through a simple method.

### EXAMPLES

Next, the present invention is described in more detail by reference to Examples, but it should be construed that the present invention is by no means limited by these Examples.

The elastic modulus of the insulating layer used in the Examples and the insulation properties of the insulating layer and the heat dissipation layer and so on before and after lamination, and furthermore, the output and flex resistance of the prepared thermoelectric conversion module were evaluated by the following methods.

### (a) Elastic Modulus

The elastic modulus (GPa) at 23° C. of the insulating layer was measured with a nanoindenter (“Nanoindentor DCM”, manufactured by MTS) under the following condition.
Indenter shape: Triangular pyramid
Indentation depth: 10 μm
Oscillation frequency: 45 Hz
Drift velocity: 0.5 nm/sec
Sample Poisson's ratio: 0.25
Surface detection threshold: 5%

### (b) Evaluation of Insulation Properties

After forming the thermoelectric element layer, an electric resistance value between output electrodes of the both terminals of the thermoelectric element layer immediately after the annealing treatment and an electric resistance value between output electrodes of the both terminals of the thermoelectric element layer of the thermoelectric element module having the insulating layer, the heat dissipation layer, and so on laminated thereon were measured with DIGITAL HiTESTER (Model name: 3801-50, manufactured by Hioki E.E. Corporation) in the environment at 25° C. and 50% RH, thereby evaluating the insulation properties. Here, if the electric resistance value after preparing the thermoelectric conversion module is at least not lowered as compared with the electric resistance value immediately after the annealing treatment, the resultant is free from the generation of a short circuit within the thermoelectric conversion module and has insulation properties.

### (c) Evaluation of Electromotive Force

By keeping one face of the prepared thermoelectric conversion module in a heated state at 50° C. by a hot plate and cooling the other face to 20° C. by a water-cooled heat sink, thereby giving a temperature difference of 30° C., an electromotive force from the output electrodes of the both terminals of the thermoelectric element layer of the thermoelectric conversion module was measured with DIGITAL HiTESTER (Model name: 3801-50, manufactured by Hioki E.E. Corporation). Typically, the generation of a short circuit results in a lowering of the electromotive force.

### (d) Evaluation of Flex Resistance

With respect to the prepared thermoelectric conversion module, the flex resistance of the thermoelectric conversion module according to the insulation properties was evaluated by using a polypropylene-made round bar (diameter: 45 mm). The prepared thermoelectric conversion module was wound around the round bar, and an electric resistance value between the output electrodes of the thermoelectric element module was measured in each of the state before winding (before the test) and the wound state under the same condition as in (b) and evaluated according the following criteria. The winding around the round bar was performed in such a manner that the insulating layer was positioned outside.

A: A lowering of the electric resistance value between the output electrodes of the thermoelectric element module in the wound state from the state before the test is less than 5%.

B: A lowering of the electric resistance value between the output electrodes of the thermoelectric element module in the wound state from the state before the test is 5% or more and less than 10%.

C: A lowering of the electric resistance value between the output electrodes of the thermoelectric element module in the wound state from the state before the test is 10% or more.

### <Preparation of Thermoelectric Element Layer>

FIG. 4 is a plan view showing a configuration of the thermoelectric element layer used in the Examples, in which (a) shows a disposition of electrodes formed on a film substrate, and (b) shows a disposition of P-type and N-type thermoelectric elements formed on electrodes.

A copper foil-stuck polyimide film substrate (a product name; UPISEL N, manufactured by Ube Exsymo Co., Ltd., polyimide substrate thickness: 50 μm, copper foil: 9 μm) was prepared, and the copper foil on a polyimide film substrate 12 was wet etched with a ferric chloride solution, thereby forming an electrode pattern of a disposition corresponding to the arrangement of P-type and N-type thermoelectric elements as mentioned later. A nickel layer (thickness: 9 μm) was laminated on the patterned copper foil by means of electroless plating, and subsequently, a gold layer (thickness: 40 nm) was laminated on the nickel layer by means of electroless plating, thereby forming a pattern layer of an electrode 13. Thereafter, coating liquids (P) and (N) as mentioned later were applied onto the electrode 13 on the polyimide film substrate 12, and a pair of a P-type thermoelectric element 15 of 1 mm×6 mm and an N-type thermoelectric element 14 of 1 mm×6 mm were alternately disposed adjacent to each other so as to come into contact with each in a side of 6 mm, thereby preparing a thermoelectric element layer 16 in which 380 pairs of the P-type thermoelectric element and the N-type thermoelectric element were provided within the plane of the polyimide film substrate 12 such that they were electrically made in series. Actually, 38 pairs of the P-type thermoelectric element 15 and the N-type thermoelectric element 14 connected with each other were defined as one row, and this was provided in 10 rows. In FIG. 4, an electrode 13a is an electrode for connection of each row of the thermoelectric element layer 16, and an electrode 13b is an electrode for outputting an electromotive force.

### (Preparation Method of Thermoelectric Semiconductor Fine Particles)

P-Type bismuth telluride Bi_{0.4}Te₃Sb_{1.6} (manufactured by Kojundo Chemical Laboratory Co., Ltd., particle diameter: 180 μm) that is a bismuth-tellurium-based thermoelectric semiconductor material was pulverized in a nitrogen gas atmosphere by using a planetary ball mill (Premium line P-7, manufactured by Fritsch Japan Co., Ltd.), thereby preparing thermoelectric semiconductor fine particles T1 having an average particle diameter of 1.2 μm. With respect to the thermoelectric semiconductor fine particles obtained through pulverization, the particle size distribution was measured with a laser diffraction particle size analyzer (MASTERSIZER 3000, manufactured by Malvern Panalytical Ltd.).

N-type bismuth telluride Bi₂Te₃ (manufactured by Kojundo Chemical Laboratory Co., Ltd., particle diameter: 180 μm) that is a bismuth-tellurium-based thermoelectric semiconductor material was pulverized in the same manner as mentioned above, thereby preparing thermoelectric semiconductor fine particles T2 having an average particle diameter of 1.4 μm.

### (Preparation of Thermoelectric Semiconductor Composition) Coating Liquid (P)

A coating liquid (P) composed of a thermoelectric semiconductor composition obtained by mixing and dispersing 90 parts by mass of the obtained fine particles T1 of a p-type bismuth-tellurium-based thermoelectric semiconductor material, 5 parts by mass of, as a heat-resistant resin, polyamic acid (a poly(pyromellitic dianhydride-co-4,4′-oxydianiline)amide acid solution, manufactured by Sigma-Aldrich, solvent: N-methylpyrrolidone, solid content concentration: 15% by mass) that is a polyimide precursor, and 5 parts by mass of, as an ionic liquid, [1-butyl-3-(2-hydroxyethyl)pyridinium bromide] was prepared.

### Coating Liquid (N)

A coating liquid (N) composed of a thermoelectric semiconductor composition obtained by mixing and dispersing 90 parts by mass of the obtained fine particles T2 of an n-type bismuth-tellurium-based thermoelectric semiconductor material, 5 parts by mass of, as a heat-resistant resin, polyamic acid (a poly(pyromellitic dianhydride-co-4,4′-oxydianiline)amide acid solution, manufactured by Sigma-Aldrich, solvent: N-methylpyrrolidone, solid content concentration: 15% by mass) that is a polyimide precursor, and 5 parts by mass of, as an ionic liquid, [1-butyl-3-(2-hydroxyethyl)pyridinium bromide] was prepared.

### (Formation of Thermoelectric Element Layer)

As shown in FIG. 4(b), the above-prepared coating liquid (P) was applied in a predetermined position on the polyimide film substrate 12 in which the aforementioned electrode pattern had been formed by the screen printing method, which was then dried in an argon atmosphere at a temperature of 150° C. for 10 minutes, thereby forming a thin film having a thickness of 50 μm. Subsequently, the above-prepared coating liquid (N) was similarly applied in a predetermined position on the aforementioned polyimide film, which was then dried in an argon atmosphere at a temperature of 150° C. for 10 minutes, thereby forming a thin film having a thickness of 50 μm.

Furthermore, each of the obtained thin films was subjected to temperature elevation in a mixed gas atmosphere of hydrogen and argon (hydrogen/argon=3% by mass/97% by mass) at a temperature rise rate of 5 K/min and then held at 325° C. for 30 minutes, and an annealing treatment after the thin film formation was performed to undergo crystal growth of the fine particles of the thermoelectric semiconductor material. There was thus formed a thermoelectric element layer composed of the P-type thermoelectric element layer and the N-type thermoelectric element layer.

### Example 1

### <Preparation of Thermoelectric Conversion Module>

100 parts by mass of a copolymer of isobutylene and isoprene (Exxon Butyl 268, manufactured by Japan Butyl Co., Ltd., number average molecular weight: 260,000, isoprene content: 1.7 mol %), 5 parts by mass of a polyisoprene rubber having a carboxylic acid-based functional group (LIR410, manufactured by Kuraray Co., Ltd., number average molecular weight: 30,000, average number of carboxy group per molecule: 10), 20 parts by mass of an aliphatic petroleum resin (QUINTONE A100, manufactured by Zeon Corporation, softening point: 100° C.), and 1 part by mass of a crosslinking agent (epoxy resin: TC-5, manufactured by Mitsubishi Chemical Corporation) were dissolved in toluene, thereby obtaining an adhesive composition 1 having a solid content concentration of 25%.

This adhesive composition 1 was applied on a release-treated face of a release film (a trade name: SP-PET382150, manufactured by Lintec Corporation); the obtained coating film was dried at 100° C. for 2 minutes, to form an adhesive layer having a thickness of 25 μm; and a release-treated face of other release film (a trade name: SP-PET381031, manufactured by Lintec Corporation) was stuck thereon, to obtain an adhesive sheet 1. The formed adhesive layer is a sealing layer as the covering layer and has adhesiveness.

Subsequently, a PET film (a trade name: Ester Film E5100, manufactured by Toyobo Co., Ltd., thickness: 12 μm, elastic modulus: 4.0 GPa) as the insulating layer was used, on the top and bottom of which was then laminated the adhesive layer of the adhesive sheet 1 (thickness: 25 μm, elastic modulus: 0.0002 GPa), respectively, and the resultant was configured as an insulating layer 1.

The insulating layer 1 was stuck onto the face of the obtained thermoelectric element layer on the opposite side to the substrate; an adhesive layer (thickness: 25 μm, elastic modulus: 0.0002 GPa) of the adhesive sheet 1 was stuck onto the face of the substrate on the opposite side to the thermoelectric element layer; and heat dissipation layers composed of a stripe-shaped high thermal conductive material (oxygen-free copper striped plate C1020, thickness: 100 μm, width: 1 mm, length: 100 mm, gap: 1 mm, thermal conductivity: 398 W/(m·K)) were disposed alternately in the upper part and lower part of a site where a P-type thermoelectric element and an N-type thermoelectric element were adjacent to each other via the respective layers, thereby preparing a thermoelectric conversion module,

### Example 2

A thermoelectric conversion module was prepared in the same manner as in Example 1, except for changing the insulating layer to a nylon-based film (a trade name: HARDEN Film N1100, manufactured by Toyobo Co., Ltd., thickness: 12 μm, elastic modulus: 1.5 GPa).

### Example 3

A thermoelectric conversion module was prepared in the same manner as in Example 1, except for changing the insulating layer to an LLDPE-based film (a trade name: UB-3, manufactured by Tamapoly Co., Ltd., thickness: 50 μm, elastic modulus: 0.2 GPa).

### Example 4

100 parts by mass of an imino-type methylated melamine resin (a trade name: MX730, manufactured by Nippon Carbide Industries Co., Inc., mass average molecular weight: 1,508), 0.1 parts by mass of polyester-modified hydroxy group-containing polydimethylsiloxane (a trade name: BYK-370, manufactured by BYK Japan KK, mass average molecular weight: 5,000), and 8 parts by mass of p-toluenesulfonic acid (a trade name: Drier 900, manufactured by Hitachi Chemical Polymer Co., Ltd.) were mixed with toluene as a solvent, thereby preparing a coating liquid having a solid content concentration of 15% by mass. This was defined as a coating agent 1.

A heat dissipation layer composed of a stripe-shaped high thermal conductive material (oxygen-free copper striped plate C1020, thickness: 100 μm, width: 1 mm, length: 100 mm, gap: 1 mm, thermal conductivity: 398 W/(m·K)) was dipped in the coating agent 1 and then taken out, followed by drying in a thermostat at 120° C. for 60 seconds in a nitrogen atmosphere to perform a coating treatment (thickness: 0.1 μm, elastic modulus: 6.0 GPa). This was defined as a coating-treated heat dissipation layer.

A thermoelectric conversion module was prepared in the same manner as in Example 1, except for using the insulating layer 1 as the adhesive sheet 1 (thickness: 25 μm, elastic modulus: 0.0002 GPa) and changing the heat dissipation layer on the insulating layer 1 to the coating-treated heat dissipation layer.

### Comparative Example 1

Two sheets of the adhesive layer of the adhesive sheet 1 (thickness: 25 μm, elastic modulus: 0.0002 GPa) were stuck onto each other, thereby preparing an adhesive sheet 2.

A thermoelectric conversion module was prepared in the same manner as in Example 1, except for changing the insulating layer 1 to the adhesive sheet 2.

The evaluation results of the elastic modulus of the insulating layer used in the Examples and the insulation properties of the insulating layer and the heat dissipation layer and so on before and after lamination, and furthermore, the electromotive force and flex resistance of the prepared thermoelectric conversion module are shown in Table 1.

TABLE 1

| | | | | | | Thermoelectric | | | | |
|---|---|---|---|---|---|---|---|---|---|---|
| | | | | | | element layer | | | | |
| | | | | | | (Immediately | | | | |
| | | | | | Heat | after | Thermoelectric conversion module | | | |
| | | Insulating layer | | | dissipation | annealing | | Electro- | | |
| | Covering | | Elastic | Forming site | layer | treatment) | | motive | | |
| | layer | | modulus | (Part of layer | Material | Resistance | Resistance | force | Insulation | Flex |
| | Kind | Kind | (GPa) | configuration) | (disposed) | (Ω) | (Ω) | (V) | properties | resistance |
| Exam- | Polyolefin- | PET | 4 | On covering layer | Copper | 419 | 670 | 0.532 | Yes | A |
| ple 1 | based | | | (Covering layer/ | (both faces) | | | | | |
| | | | | thermoelectric | | | | | | |
| | | | | element | | | | | | |
| | | | | layer/substrate) | | | | | | |
| Exam- | Polyolefin- | Nylon- | 1.5 | On covering layer | Copper | 379 | 652 | 0.467 | Yes | A |
| ple 2 | based | based | | (Covering layer/ | (both faces) | | | | | |
| | | N1100 | | thermoelectric | | | | | | |
| | | | | element | | | | | | |
| | | | | layer/substrate) | | | | | | |
| Exam- | Polyolefin- | LLDPE | 0.2 | On covering layer | Copper | 488 | 543 | 0.322 | Yes | A |
| ple 3 | based | UB-3 | | (Covering layer/ | (both faces) | | | | | |
| | | | | thermoelectric | | | | | | |
| | | | | element | | | | | | |
| | | | | layer/substrate) | | | | | | |
| Exam- | Polyolefin- | Melamine- | 6 | On covering layer | Copper | 387 | 632 | 0.444 | Yes | A |
| ple 4 | based | based | | [covered | (both faces) | | | | | |
| | | | | on heat dissipation | | | | | | |
| | | | | layer] | | | | | | |
| | | | | (Covering layer/ | | | | | | |
| | | | | thermoelectric | | | | | | |
| | | | | element | | | | | | |
| | | | | layer/substrate) | | | | | | |
| Compar- | Polyolefin- | — | — | — | Copper | 448 | 308 | 0.088 | No | C |
| ative | based | | | | (both faces) | | | | | |
| Exam- | | | | | | | | | | |
| ple 1 | | | | | | | | | | |

In Examples 1 to 3 in which the insulating layer having an elastic modulus of a specified range is included between the thermoelectric element layer and the heat dissipation layer of the thermoelectric conversion module, it is noted that the short circuit is not generated, the explicitly superior electromotive force is obtained, and the flex resistance is revealed, as compared with Comparative Example 1 using the adhesive layer not having an elastic modulus of a specified range (covering layer:sealing layer, elastic modulus: 0.0002 GPa). In addition, it is noted that the same is also applicable to Example 4 including the thermoelectric element layer of the thermoelectric conversion module and the heat dissipation layer covered directly by the insulating layer.

It is noted from the aforementioned results that the thermoelectric conversion module of the present invention is maintained in terms of a thermoelectric performance and is excellent in insulation properties.

### INDUSTRIAL APPLICABILITY

In view of the fact that the thermoelectric conversion module of the present invention has excellent insulation properties, it is expected that it can be more suitably used as a thermoelectric conversion module for an installation face having an electric conductive site (e.g., an external heat exhaust face or a heat discharging face) and/or a thermoelectric conversion module including a heat dissipation layer having an electric conductive site.

### REFERENCE SIGNS LIST

1A, 1B, 1C: Thermoelectric conversion module

2: Substrate

3: Electrode

4: N-type thermoelectric element layer

5: P-type thermoelectric element layer

6: Thermoelectric element layer

7: Covering layer

8a, 8b: Heat dissipation layer

9: Insulating layer

12: Polyimide film substrate

13: Electrode

13a: Electrode for connection of each row of thermoelectric element layer

13b: Electrode for outputting electromotive force

14: N-Type thermoelectric element

15: P-Type thermoelectric element

16: Thermoelectric element layer (including electrode part)

1. A thermoelectric conversion module, comprising:
a thermoelectric element layer;
an insulating layer; and
a heat dissipation layer on at least one face of the thermoelectric element layer via the insulating layer,
wherein the thermoelectric element layer is one in which a P-type thermoelectric element layer and an N-type thermoelectric element layer are alternately arranged to be adjacent to each other in a in-plane direction and disposed in series, and
the insulating layer has an elastic modulus at 23° C. of 0.1 to 500 GPa.

2. The thermoelectric conversion module according to claim 1, wherein the insulating layer is composed of a resin or an inorganic material.

3. The thermoelectric conversion module according to claim 1, wherein the insulating layer has a thickness of 1 to 150 μm.

4. The thermoelectric conversion module according to claim 1, further comprising: a substrate on other face of the thermoelectric element layer.

5. The thermoelectric conversion module according to claim 4, further comprising:
a heat dissipation layer on a face of the substrate on a side opposite to the thermoelectric element layer.

6. The thermoelectric conversion module according to claim 1, wherein the heat dissipation layer is composed of at least one selected from the group consisting of a metal material, a ceramic material, a mixture of a metal material and a resin, and a mixture of a ceramic material and a resin.

7. The thermoelectric conversion module according to claim 1, wherein the dissipation layer has a thermal conductivity of 5 to 500 W/(m·K).

8. The thermoelectric conversion module according to claim 4, wherein the substrate is a film substrate.

9. The thermoelectric conversion module according to claim 1, further comprising a covering layer.

10. A method of producing a thermoelectric conversion module which is the thermoelectric convention module according to claim 1, the method comprising:
forming the thermoelectric element layer;
forming the insulating layer; and
forming the heat dissipation layer, wherein the insulating layer has an elastic modulus at 23° C. of 0.1 to 500 GPa.
